(19) United States
(12) Patent Application Publication
(10) Pub. No.: US 2002/0009893 A1
(43) Pub. Date: Jan. 24, 2002

(54) Method of forming a conductor in a fluoride silicate glass (FSG) layer

(76) Inventors: Chia-Chi Chung, Hsin-Chu City (TW); Kuang-Yu Huang, Miao-Li Hsien (TW)

Correspondence Address: WINSTON HSU, SF. 389, FU-HO ROAD, YUNGHO CITY, TAIPEI, TW

(21) Appl. No.: 09/682,050

(22) Filed: Jul. 15, 2001

(30) Foreign Application Priority Data
Jul. 21, 2000 (TW) 089114593

(51) Int. Cl. H01L 21/302; H01L 21/461

(52) U.S. Cl. 438/710

(57) ABSTRACT

A fluoride silicate glass (FSG) layer, comprising a plasma enhanced oxide layer (PEOX layer) on a surface of the FSG layer, is positioned on a substrate of a semiconductor wafer. An etching tank, employed as a plug hole or a trench, is formed in the FSG layer. A first plasma ashing process, using oxygen or a gas mixture of nitride and hydrogen as a reacting gas, is then performed to remove fluorine atoms for a predetermined thickness of a surface of the etching tank. A wet cleaning process is performed thereafter. By performing a second plasma ashing process, using oxygen or a gas mixture of nitride and hydrogen as a reacting gas, residual fluorine atoms are removed for the predetermined thickness of the surface of the etching tank. Finally, the etching tank is filled with a conductive material so as to form a conductor.

### BACKGROUND OF THE INVENTION

1. Field of the Invention

The present invention relates to a method of forming a conductor in a fluoride silicate glass (FSG) layer, and more specifically, to a method of preventing a conductor formed in a FSG layer from corrosion by hydro fluoric acid (HF).

2. Description of the Prior Art

With the shrinking of connecting wires in wafer production, an interlevel dielectric (ILD) layer between two metallic connecting layers is normally comprised of a substance with a lower dielectric constant and excellent gap-filling properties, such as fluorinated silicate glass (FSG). Since fluoride exhibits a strong electronegative behavior, it can reduce the polarizability of a silicon oxide ILD layer in the Si—O—F network, so as to reduce the dielectric constant of the silicon oxide ILD and prevent the parasitic capacitance, which would interfere with the transmission speed of the signals above or below the ILD layer. In addition, since fluorine is a strong etching species, it would incur a deposition/etching effect during the deposition of FSG, helping to form a void-free FSG thin film in wafer production with a wire-narrowing requirement.

However, an FSG layer is not stable because of a chemical instability property and would lead to the severe integration concerns. For example, moisture absorption on a surface would happen and cause cloudy haze and even bubbles forming on the FSG layer, thus increasing the dielectric constant of the FSG layer and interfering with later wafer making processes. Moreover, the free fluorine existing within the FSG lattice or accumulated on the surface of the FSG layer can easily bind to the water molecules generated from the FSG deposition or to the ones existing in the atmosphere, forming hydrofluoric acid (HF), resulting in the corrosion or destruction of later-formed metallic connecting wires or anti-reflection layer.

A baking process is thus frequently performed in a chamber after the FSG layer is formed so as to remove moisture absorbed on the FSG layer during the deposition of the FSG layer. In subsequent processes, the semiconductor wafer with the FSG layer is prevented from moisture reabsorption due to work-in-process queuing or distributed manufacturing (i.e., one process step is performed in one factory location, and a subsequent processing step is performed in another factory location).

Alternatively, an undoped silicon glass (USG) layer, employed as a cap layer, is immediately formed on the FSG layer after the FSG layer is formed so as to prevent moisture absorption to the FSG layer.

However, the manufacturing throughput is thus reduced due to the complicated processes. In addition, multiple plug holes need to be formed in the dielectric layers in the subsequent multilevel metallization process to further form contact plugs and via plugs, both employed as conductive wires electrically connecting MOS transistors with metal conductive wires. The surface of the FSG layer is thus exposed, leading to moisture absorption.

Please refer to FIG. 1 to FIG. 3 of cross-sectional views of forming a contact plug 24 according to the prior art. As shown in FIG. 1, a semiconductor wafer 10 comprises a bottom conductive layer 12, a FSG dielectric layer 14 positioned on the bottom conductive layer 12 and an USG layer 15 formed on the FSG dielectric layer 14 by a plasma-enhanced chemical vapor deposition (PECVD) process. As shown in FIG. 2, processes, including photolithography and etching, are performed to form a plug hole 16 in the dielectric layer 14 down to a surface of the bottom conductive layer 12. A cleaning process is then performed to remove polymers within the plug hole 16 and a photoresist layer on the semiconductor wafer 10. As shown in FIG. 3, a titanium layer 18, a titanium nitride layer 20 and a conductive layer 22, composed of tungsten, are respectively deposited on either the semiconductor wafer 10 or a surface of the plug hole 16. Finally, a chemical mechanical polishing (CMP) process is performed on the surface of the semiconductor wafer to evenly remove those portions of the conductive layer 22, the titanium nitride layer 20 and the titanium layer 18 directly above the USG layer 15 and the dielectric layer 14 so as to form a plug 24, having a top surface aligned with that of the dielectric layer 14, in the plug hole 16.

However, as shown in FIG. 2, the USG layer 15, used as a cap layer, is frequently over-etched after performing the etching process to form the plug hole 16. Surfaces of portions of the FSG layer 14 within the plug hole 16 are thus exposed. During the subsequent cleaning process employed to remove polymers within the plug hole 16, moisture absorption on the surfaces of portions of the FSG layer 14 within the plug hole 16 happens and causes hydrofluoric acid (HF) and cloudy haze formed on the FSG layer 14, resulting in the corrosion or destruction of later-formed metallic connecting wires or anti-reflection layer, and a flawed process yield rate.

### SUMMARY OF INVENTION

It is therefore a primary object of the present invention to provide a method of forming a conductor in a fluoride silicate glass (FSG) layer so as to prevent corrosion of hydro fluoric acid (HF).

According to the claimed invention, a FSG layer is positioned on a surface of a semiconductor wafer. An etching tank is then formed in the FSG layer. A first plasma ashing process is performed to remove fluorine atoms from a predetermined thickness of a surface of the etching tank thereafter. A wet cleaning process is then performed. Finally, a second plasma ashing process is performed to further remove fluorine atoms from the predetermined thickness of the surface of the etching tank. By filling the etching tank with a conductive material, a conductor is formed at the end of the embodiment of the present invention.

It is an advantage of the present invention against the prior art that the first plasma ashing process is performed to remove fluorine atoms from the predetermined thickness of a surface of the etching tank as well as to remove the photoresist layer from the semiconductor wafer after the etching process. A wet cleaning process is then performed to remove polymers within the etching tank. Hydrofluoric acid (HF) formed on the FSG layer due to the free fluorine existing within the FSG lattice or accumulated on the surface of the FSG layer is thus prevented. In addition, a second plasma ashing process is performed to further remove fluorine atoms from the predetermined thickness of the surface of the etching tank. Hydrofluoric acid (HF), resulting in the corrosion or destruction of later-formed metallic connecting wires or anti-reflection layer, formed on the FSG layer due to the reactions between the water molecules existing in the atmosphere and the free fluorine existing within the FSG lattice or accumulated on the surface of the FSG layer is thus prevented. Consequently, the process yield rate is significantly improved.

These and other objectives of the present invention will no doubt become obvious to those of ordinary skill in the art after reading the following detailed description of the preferred embodiment, which is illustrated in the multiple figures and drawings.

### BRIEF DESCRIPTION OF THE DRAWINGS

FIG. 1 to FIG. 3 are cross-sectional views of forming a contact plug according to the prior art.

FIG. 4 to FIG. 9 are cross-sectional views of forming a dual damascene structure according to the present invention.

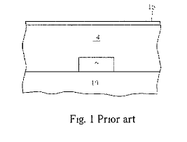

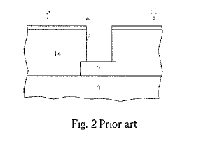

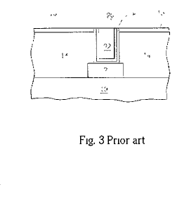

### DETAILED DESCRIPTION

The present invention provides a method of forming a conductor, employed as a contact plug, a via plug, a conductive wire or a conductive wire with a dual damascene structure, in a fluoride silicate glass (FSG) layer. For simplicity of description, a method of forming a dual damascene structure is described in subsequent paragraphs as the preferred embodiment of the present invention.

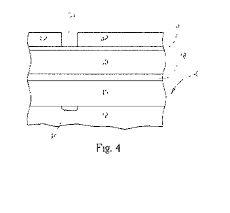

Please refer to FIG. 4 to FIG. 9 of cross-sectional views of forming a dual damascene structure 72 according to the present invention. As shown in FIG. 4, a semiconductor wafer 40 comprises a substrate 42, a conductive layer positioned in a predetermined area in the substrate 42, a FSG layer, employed as a first inter layer dielectric (ILD) layer 46, positioned on the conductive layer 44, a silicon-oxy-nitride (SiOₓN_{y}) layer 48 positioned on the first ILD layer 46, another FSG layer, employed as a second ILD layer 50, positioned on the silicon-oxy-nitride layer 48 and an undoped silicate glass (USG) layer 51, formed by a plasma-enhanced chemical vapor deposition (PECVD) process and employed as a cap layer of the first ILD layer 46, positioned on the second ILD layer 50. A first lithography process is performed to evenly coat a first photoresist layer 52 on the USG layer 51. An opening 54 is then formed on portions of the first photoresist layer 52 atop the conductive layer 44 to define a via pattern.

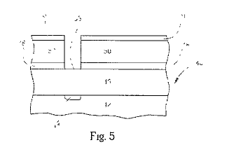

As shown in FIG. 5, an anisotropic dry etching process is performed through the opening 54 to remove portions of the USG layer 51, the second ILD layer 50 and silicon-oxy-nitride layer 48 not covered by the first photoresist layer 52 down to a surface of the first ILD layer 46 so as to form a hole 56. The first photoresist layer 52 is then removed by performing a resist stripping process.

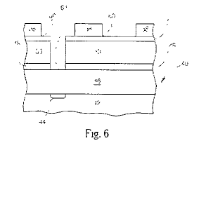

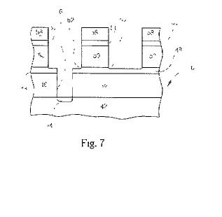

As shown in FIG. 6, a second lithography process is performed to evenly coat a second photoresist layer 58 on the USG layer 51. Two line-shaped openings 60 are then formed in the second photoresist layer 58 to define a wiring line pattern. As shown in FIG. 7, a dry etching process is performed to etch portions of the USG layer 51, the second ILD layer 50, silicon-oxy-nitride layer 48 and the first ILD layer 46 through the line-shaped opening 60 and the hole 56 respectively down to the surface of the silicon-oxy-nitride layer 48 and that of the substrate 42 to form two line-shaped trench 62 and a via hole 64, respectively.

A first plasma ashing process, using oxygen, having a flow rate ranging from 500 to 2500 standard cubic centimeters per minute (sccm), or a gas mixture of nitride and hydrogen, having a flow rate ranging from 200 to 1500 sccm and the hydrogen forming 4% to 5% of the gas mixture, as a reacting gas, is then performed on the semiconductor wafer 40 in a vacuum chamber, having an inner pressure ranging from 500 to 1500 mTorrs, with a radio frequency power (RF power) ranging from 1000 to 1800 Watts at a temperature ranging from 200 to 270° C. to remove the second photoresist layer 58 and react with exposed surfaces of the FSG layers within the line-shaped trenches 62 and the via hole 64 so as to remove fluorine atoms from a predetermined thickness of the exposed surfaces of the FSG layers. Free fluorine atoms accumulated in FSG lattices and on surfaces of the line-shaped trenches 62 and the via hole 64 are thus removed. In another embodiment of the present invention, a gas mixture of oxygen, hydrogen and nitride is employed as the reacting gas of the first plasma ashing process.

A wet cleaning process, using an organic solution comprising a chelator and an inhibitor as a cleaning solution, is performed thereafter to remove residual polymers with the line-shaped trenches 62 and the via hole 64. Finally, a second plasma ashing process is performed under process conditions the same as those of the first plasma ashing process to enhance the removal of fluorine atoms from the predetermined thickness of the exposed surfaces of the FSG layers.

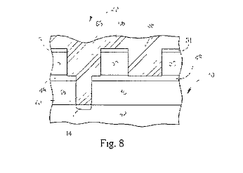

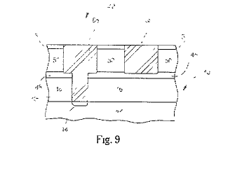

As shown in FIG. 8, a metal layer 66 is then formed to cover the semiconductor wafer 40 and fill both the line-shaped trenches 62 and the via hole 64. A metal conductive wire 68 and a via plug 70 are thus formed. As shown in FIG. 9, a chemical mechanical polishing (CMP) process is performed at the end of the method to remove portions of the metal layer 66 on either the USG layer 51 or the second ILD layer 50 so that a surface of the metal conductive wire 68 is aligned with that of the USG layer 51.

In comparison with the prior art, the first plasma ashing process, using oxygen or a gas mixture of nitride and hydrogen as a reacting gas, is performed to remove fluorine atoms from the predetermined thickness of surfaces of the line-shaped trenches 62 and the via hole 64, as well as to remove the photoresist layer 58 from the semiconductor wafer 40 after the etching process. The wet cleaning process is then performed to remove polymers within the line-shaped trenches 62 and the via hole 64. Hydrofluoric acid (HF) and cloudy haze, both formed due to the free fluorine existing within the FSG lattice or accumulated on surfaces of the line-shaped trenches 62 and the via hole 64, are thus prevented. Finally, a second plasma ashing process, using oxygen or a gas mixture of nitride and hydrogen as a reacting gas, is performed to further remove fluorine atoms from the predetermined thickness of the surface of the etching tank. Hydrofluoric acid (HF), resulting in a increased resistance of the product and the corrosion or destruction of later-formed metallic connecting wires or anti-reflection layer, form due to the reactions between the water molecules existing in the atmosphere and the free fluorine existing within the FSG lattice or accumulated on the surface of the FSG layer is thus prevented. Consequently, the transmission speed of the signals between ILD layers is increased by the reduced capacitance, and the process yield rate is significantly improved as well.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A method of forming a conductor in a fluoride silicate glass (FSG) layer positioned on a substrate of a semiconductor wafer, the method comprising:
forming an etching tank in the FSG layer;
performing a surface treatment on the semiconductor wafer to remove fluorine atoms from a predetermined thickness of a surface of the etching tank; and
filing the etching tank with a conductive material.

2. The method of claim 1 wherein the etching tank is a plug hole through to a surface of the substrate, and the conductor is a via plug.

3. The method of claim 1 wherein the etching tank is a trench through to a surface of the substrate, and the conductor is a conductive wire.

4. The method of claim 1 wherein the etching tank is a trench comprising a plurality of via holes through to the surface of the substrate to make the conductor a conductive wire with a dual damascene structure.

5. The method of claim 1 wherein the surface treatment is a plasma ashing process employed to remove fluorine atoms from athe predetermined thickness of athe surface of the etching tank.

6. The method of claim 5 wherein a reacting gas of the plasma ashing process is oxygen, or a gas mixture of nitride and hydrogen.

7. The method of claim 6 wherein a gas flow rate of oxygen ranges from 500 to 2500 standard cubic centimeter per minute (sccm), and a gas flow rate that of the gas mixture of nitride and hydrogen, the hydrogen forming 4% to 5% of the gas mixture, ranges from 200 to 1500 sccm.

8. The method of claim 6 wherein the plasma ashing process is performed in a vacuum chamber, an inner pressure of the vacuum chamber ranging from 500 to 1500 mtorrs, with a radio frequency power (RF power) ranging from 1000 to 1800 Watts at a temperature ranging from 200 to 270° C.

9. The method of claim 5 wherein the surface treatment further comprises a wet cleaning process.

10. The method of claim 9 wherein a cleaning solution of the wet cleaning process is an organic solution comprising a chelator and an inhibitor.

11. The method of claim 1 wherein the FSG layer further comprises a plasma enhanced oxide layer (PEOX layer) on a surface of the FSG layer.

12. A method of cleaning a fluoride silicate glass (FSG)FSG layer on a surface of thea semiconductor wafer, the method comprising:
performing a first plasma ashing process on the semiconductor wafer;
performing a wet cleaning process on the semiconductor wafer; and
performing a second plasma ashing process on the semiconductor wafer.

13. The method of claim 12 wherein the FSG layer at least comprises an etching tank employed as a plug hole or a trench.

14. The method of claim 13 wherein the etching tank is employed to form a conductive wire with a dual damascene structure.

15. The method of claim 12 wherein a reacting gas of both the first and the second plasma ashing processes is composed of oxygen, hydrogen, nitride or a gas mixture of oxygen, hydrogen and nitride.

16. The method of claim 15 wherein the reacting gas of both the first and the second plasma ashing processes is oxygen with a flow rate ranging from 500 to 2500 sccm

17. The method of claim 15 wherein the reacting gas of both the first and the second plasma ashing processes is a gas mixture of hydrogen and nitride, the hydrogen forming 4% to 5% of the gas mixture, with a flow rate of the gas mixture ranging from 200 to 1500 sccm.

18. The method of claim 12 wherein both the first and the second plasma ashing processes are performed in a vacuum chamber, an inner pressure of the vacuum chamber ranging from 500 to 1500 mTorrs, with a radio frequency power (RF power) ranging from 1000 to 1800 Watts at a temperature ranging from 200 to 270° C.

19. The method of claim 12 wherein a cleaning solution of the wet cleaning process is an organic solution comprising a chelator and an inhibitor.

20. The method of claim 12 wherein the FSG layer further comprises a PEOX layer on a surface of the FSG layer.
